(19) United States
(12) Patent Application Publication
(10) Pub. No.: US 2005/0196902 A1
(43) Pub. Date: Sep. 8, 2005

(54) METHOD OF FABRICATING FILM CARRIER

(76) Inventors: Dyi-Chung Hu, Hsinchu County (TW); Chih-Kung Huang, Hsinchu City (TW); Chien-Nan Wu, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/906,681

(22) Filed: Mar. 2, 2005

(30) Foreign Application Priority Data
Mar. 2, 2004 (TW) 93105344

(51) Int. Cl. H01L 21/4763; H01L 21/48

(52) U.S. Cl. 438/121

(57) ABSTRACT

A method of fabricating a film carrier. The method comprises the steps of providing a film; forming a plurality of sprocket holes in the film; forming a metallic layer on the film; patterning the film in an etching operation to form a plurality of openings; and, patterning the metallic layer to form a plurality of metallic leads.

### CROSS-REFERENCE TO RELATED APPLICATION

This application claims the priority benefit of Taiwan application serial no. 93105344, filed on Mar. 2, 2004.

### BACKGROUND OF THE INVENTION

1. Field of the Invention

The present invention relates to a method of fabricating a carrier. More particularly, the present invention relates to a method of fabricating a film carrier.

2. Description of Related Art

With the great advance in the electronics industry, many types of multifunctional electronic products have become indispensable in our daily life. Most electronic products are driven or controlled by integrated circuits etched on a die. To protect the structurally weak die and facilitate reliable signal transmission, the die is generally enclosed within a package. In the past, many types of chip packages have been developed. The most common chip bonding techniques include wire bonding (W/B), flip chip (F/C) bonding and tape automatic bonding (TAB). In the TAB technique, a silicon chip is bonded to a film carrier. Since the chip is bonded to a thin film, the TAB package is slim, light, flexible and easy to install.

FIGS. 1A through 1J are schematic cross-sectional views showing the progression of steps for fabricating a conventional film carrier. First, as shown in FIG. 1A, a film 100 is provided. Next, an adhesive layer 110 is formed over the film 100. As shown in FIG. 1B, the film 100 is punched using a cutting tool (not shown) to form a plurality of sprocket holes 102 and a plurality of openings 104 in the film 100. The sprocket holes 102 are used for driving the film 100 forward in a subsequent automatic bonding process. As shown in FIG. 1C, a metallic layer 120 is laminated on the film 100. Through the adhesive layer 110, the bonding strength between the film 100 and the metallic layer 120 is enhanced.

As shown in FIG. 1D, a flex coating material 130 is deposited into some of the openings 104. As shown in FIGS. 1E, a first photoresist layer P10 is formed over the metallic layer 120. The first photoresist layer P10 has a plurality of first openings 01. In the meantime, a second photoresist layer P20 is formed on the surface of the film 100 away from the metallic layer 120. As shown in FIG. 1F, using the first photoresist layer P10 as an etching mask, a portion of the metallic layer 120 is removed so that the metallic layer 120 is patterned to form a plurality of metallic leads 122. Thereafter, the first photoresist layer P10 and the second photoresist layer P20 are removed to form the structure shown in FIG. 1G.

As shown in FIG. 1H, a first tin layer 140 is formed on the surface of the metallic leads 122. Next, as shown in FIG. 1I, an anti-soldering layer 150 is formed on the surface of a portion of the first tin layer 140. Thereafter, as shown in FIG. 1J, a second tin layer 160 is formed on the remaining surface of the first tin layer 140.

In the conventional method of fabricating film carrier, holes are cut using punching tools. Since the size and location of the holes in the film carrier are different for each batch of chips, a different set of cutting tools has to be made for the production of a fresh new batch of products. In other words, excessive time and labor are required for fabricating necessary cutting tools, thereby increasing the cost the film carrier.

### SUMMARY OF THE INVENTION

Accordingly, The present invention is related to a method of manufacturing a film carrier capable of shortening production cycle and lowering production cost.

According to an embodiment of the present invention, first, a film is provided. Next, a plurality of sprocket holes is formed in the film. Thereafter, a metallic layer is formed over the film. The film is patterned in an etching operation to form a plurality of openings. Finally, the metallic layer is patterned to form a plurality of metallic leads.

In an embodiment of the present embodiment, an adhesive layer may also be attached to the film after providing the film but before forming the sprocket holes or after forming the sprocket holes but before forming the metallic layer. The metallic layer is a copper layer, for example.

In addition, the method of patterning the film may include the following steps. First, a first photoresist layer is formed over the metallic layer. Thereafter, a second photoresist layer having a plurality of second openings thereon is formed over the surface of the film away from the metallic layer. Using the second photoresist layer as an etching mask, a portion of the film is removed to form the openings in the film. Finally, both the first photoresist layer and the second photoresist layer are removed. The first photoresist layer and the second photoresist layer are dry films or liquid photoresist layers, for example.

Furthermore, a flex coat material may also be deposited to fill some of the openings after forming the openings but before forming the metallic leads.

The method of patterning the metallic layer may include the following steps. First, a third photoresist layer having a plurality of third openings thereon is formed over the metallic layer. Thereafter, a back coat is formed on the surface of the film away from the metallic layer. Next, using the third photoresist layer as an etching mask, a portion of the metallic layer is removed to form the metallic leads. Finally, the third photoresist layer and the back coat are removed. Furthermore, a surface treatment of the metallic layer may be performed before forming the third photoresist layer over the metallic layer. The surface treatment includes a chemical polishing or a micro etching process, for example.

According to an embodiment, a first solder flux layer is formed on the surface of the metallic leads after forming the metallic leads. The first solder flux layer is a tin layer, for example. After forming the first solder flux layer, an anti-soldering layer is formed on the surface of a portion of the first solder flux layer. Thereafter, a second solder flux layer is formed on the remaining surface of the first solder flux layer. The second solder flux layer is a tin layer, for example. In addition, a finished product inspection may be carried out after forming the metallic leads.

In an embodiment of the present invention, an etching operation is performed to form the holes in the film so that the cost of providing a set of cutting tools for punching holes in the film can be effectively avoided. In addition, the surface of the film is flat and free of holes when the metallic layer is formed over the film. Thus, the metallic layer can adhere uniformly to the film surface and avoid any unevenness around the openings.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1J are schematic cross-sectional views showing the progression of steps of fabricating a conventional film carrier.

FIGS. 2A through 2R are schematic cross-sectional views showing the progression of steps for fabricating a film carrier according to one embodiment of the present invention.

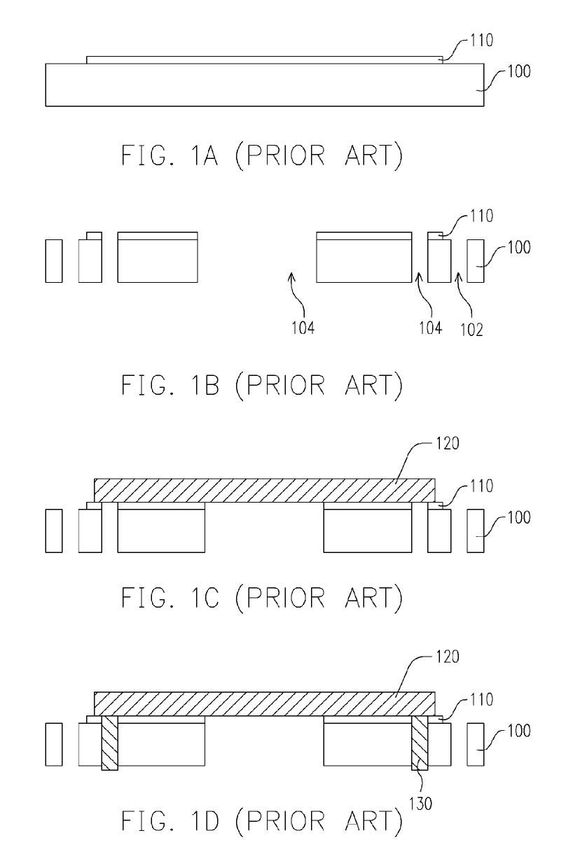

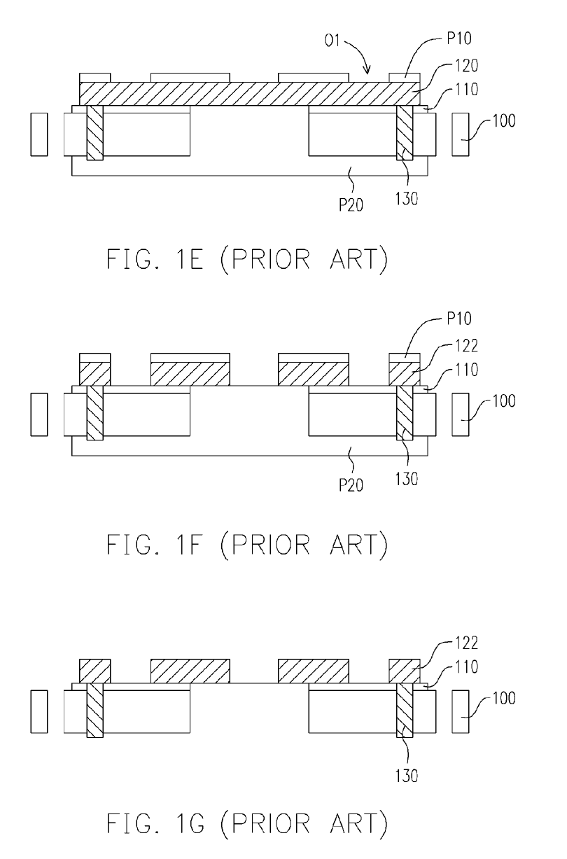

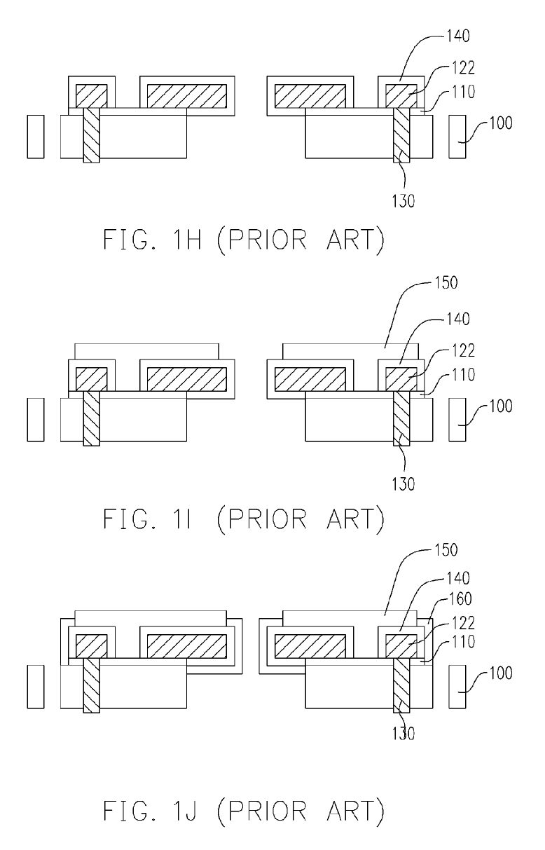

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

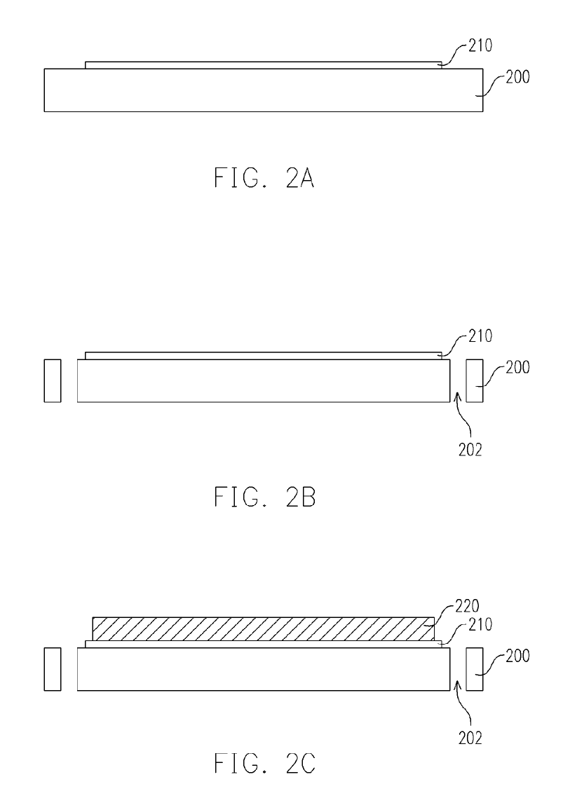

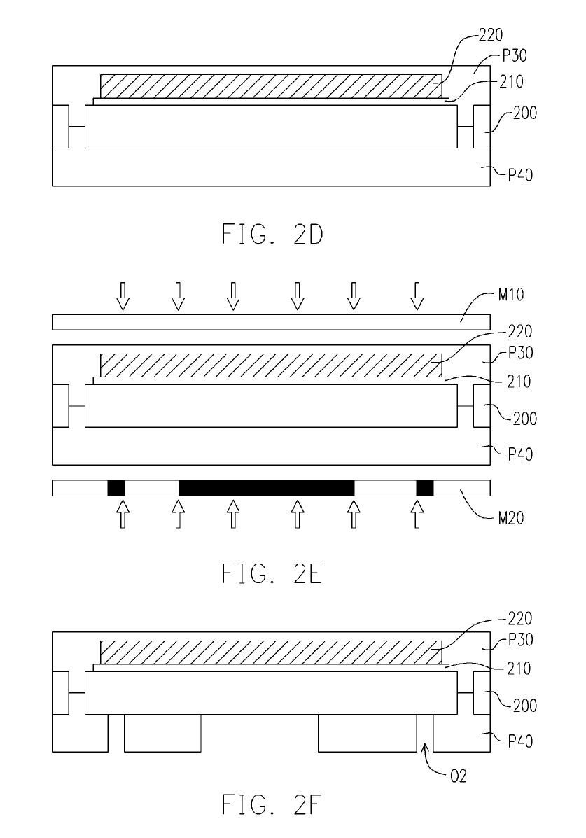

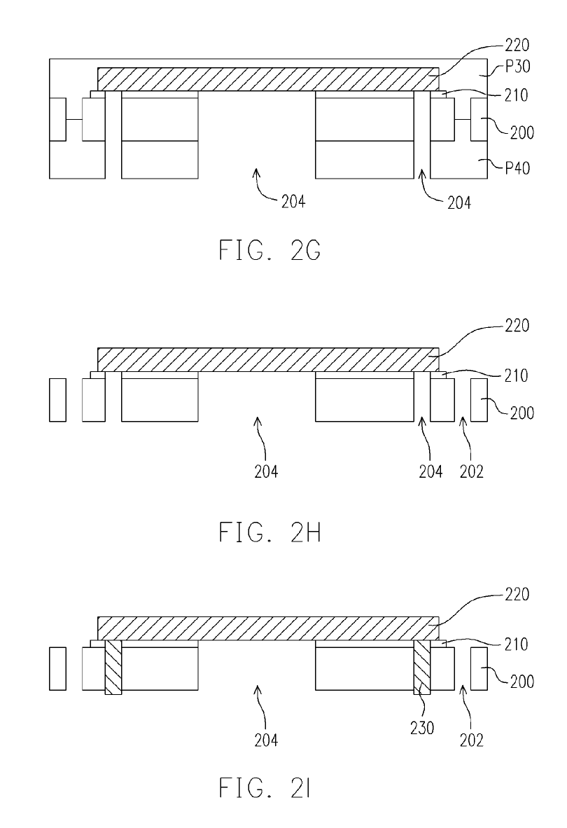

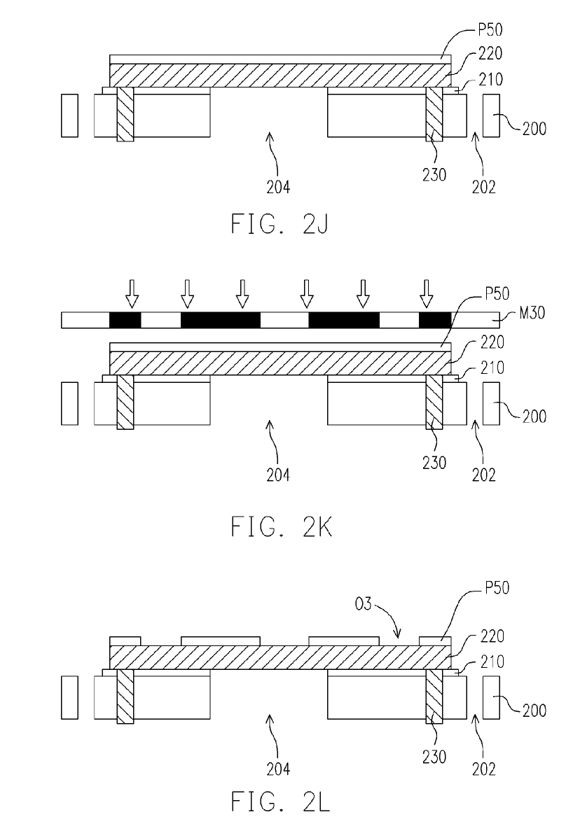

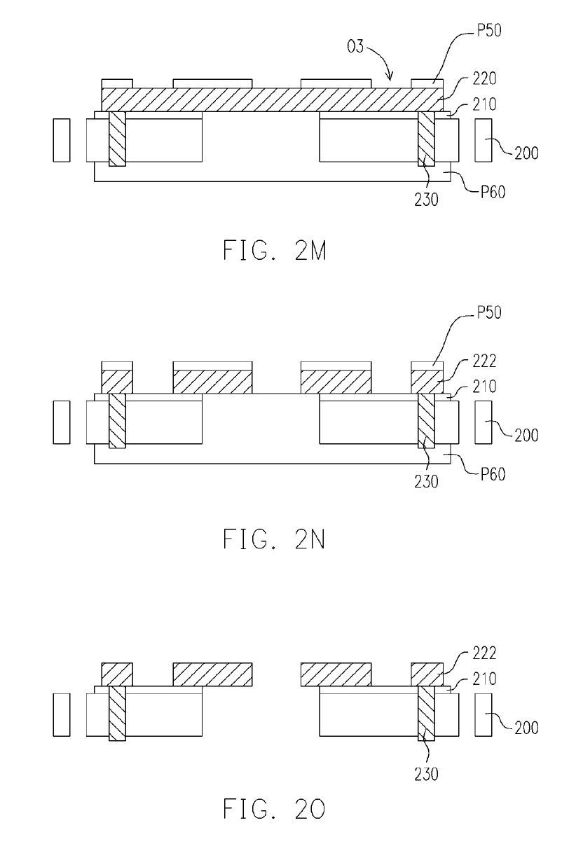

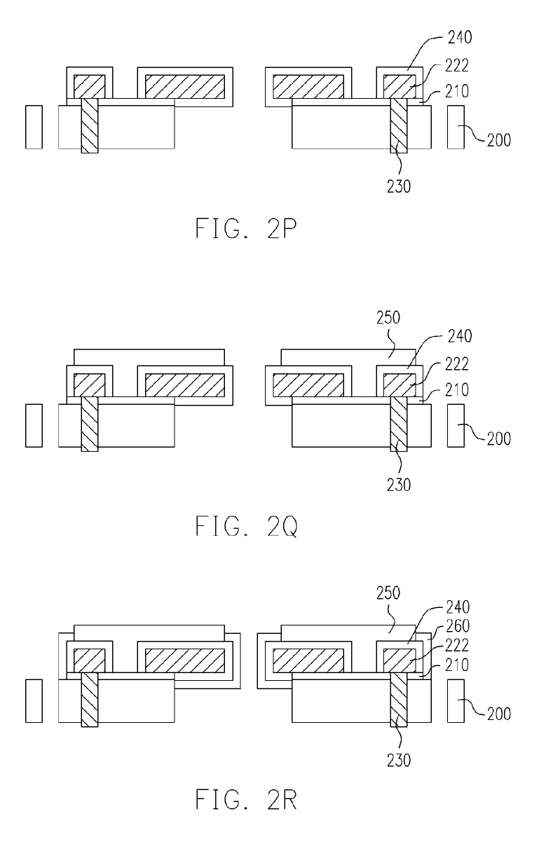

FIGS. 2A through 2R are schematic cross-sectional views showing the progression of steps for fabricating a film carrier according to one preferred embodiment of the present invention. As shown in FIG. 2A, a film 200 such as a polyimide film having an adhesive layer 210 thereon is provided. The adhesive layer 210 mainly serves to increase the adhesive strength of the film 200 with a subsequently added material layer. As shown in FIG. 2B, a plurality of sprocket holes 202 are formed in the film 200. Typically, the sprocket holes 202 are formed near the edge of the film 200 for driving the film 200 forward in a subsequent automatic bonding process. In addition, the aforementioned step may further include a suction drying process to remove moisture.

As shown in FIG. 2C, a metallic layer 220 is formed over the film 200. In the presence of the adhesive layer 210, the bonding strength between the film 200 and the metallic layer 220 is increased. The metallic layer 220 is a copper film or other conductive film disposed on the film 200 by attachment, for example.

As shown in FIG. 2D through 2H, the film 200 is patterned to form a plurality of openings 204 in an etching operation. The method of patterning the film 200 includes the following steps. First, a first photoresist layer P30 is formed over the metallic layer 220 and a second photoresist layer P40 over the film 200 on the other side of the metallic layer 220. Thereafter, a photo-exposure operation is carried out using a photomask M10 on the first photoresist layer P30 and another photomask M20 on the second photoresist layer P40. The first photoresist layer P30 is completely exposed but the second photoresist layer P40 is only partially exposed. Next, the first photoresist layer P30 and the second photoresist layer P40 are developed to form a plurality of second openings 02 in the second photoresist layer P40. Using the second photoresist layer P40 as an etching mask, a portion of the film 200 is removed to form the openings 204. Finally, the first photoresist layer P30 and the second photoresist layer P40 are removed. The first photoresist layer P30 and the second photoresist layer P40 can be dry films or liquid photoresist layers, for example.

As shown in FIG. 2I, a flex coat material is deposited into some of the openings 204 in the film 200 to form a flex coat layer 230.

As shown in FIGS. 2J through 2O, the metallic layer 220 is patterned to form a plurality of metallic leads 222. The method of patterning the metallic layer 220 includes the following steps. First, a third photoresist layer P50 is formed over the metallic layer 220. Next, the third photoresist layer P50 is exposed using a photomask M30 and then developed to form a plurality of third openings 03 in the third photoresist layer P50. Thereafter, a back coat P60 is formed over the film 200 on the other side of the metallic layer 220. The back coat P60 covers the exposed back surface of the metallic layer 220, for example, so that the back surface of the metallic layer 220 is protected from the etching solution of a subsequent etching operation. Using the third photoresist layer P50 as an etching mask, a portion of the metallic layer 220 is removed to form the metallic leads 222. Finally, the third photoresist layer P50 and the back coat P60 are removed. Furthermore, a surface treatment of the metallic layer 220 may be performed before forming the third photoresist layer P50 over the metallic layer 220 so that any oxide material on the surface of the metallic layer 220 is removed. The surface treatment may include a chemical polishing or a micro etching process, for example.

As shown in FIGS. 2P through 2R, a first solder flux layer 240 is formed on the surface of the metallic leads 222. The first solder flux layer 240 is a tin layer formed, for example, by performing an electroplating or an electroless plating process. Thereafter, an anti-soldering layer 250 is formed over the surface of a portion of the first solder flux layer 240. The anti-soldering layer 250 prevents the formation of too large a contact area between the bump and the metallic leads 222 in a subsequent packaging process so that there is insufficient separation between the chip and the metallic leads 222. After forming the anti-soldering layer 250, a second solder flux layer 260 may also be formed on the remaining surface of the first solder flux layer 240. The second solder flux layer 260 is a tin layer, for example. When the aforementioned steps are completed, a visual inspection of the finished product is carried out to ensure all the metallic leads are in perfect shape and free from any shorting or broken edges that may affect the yield.

In summary, the present invention uses photolithographic and etching processes to form all the openings in the film. Therefore, there is no need to fabricate a set of cutting tools when the punching process is used to form the openings. Although the sprocket holes are still formed using a set of cutting tools in a punching process, the same set of tools can be used on any new products. Hence, the cost of producing cutting tools is significantly reduced. Moreover, the metallic layer is formed over the film prior to forming the openings in the film. Thus, the metallic layer can adhere uniformly to the film surface and avoid any unevenness around the openings. Ultimately, product yield of the film carrier is improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method of fabricating a film carrier, comprising the steps of:
providing a film;
forming a plurality of sprocket holes in the film;
forming a metallic layer over the film;
etching the film to form a plurality of openings through an etching operation; and
etching the metallic layer to form a plurality of metallic leads.

2. The method of claim 1, further comprising a step of forming an adhesive layer over the film after the step of providing the film but before the step of forming the sprocket holes.

3. The method of claim 1, further comprising a step of forming an adhesive layer over the film after the step of forming the sprocket holes but before the step of forming the metallic layer.

4. The method of claim 1, wherein the metallic layer comprises a copper layer.

5. The method of claim 1, wherein the step of patterning the film comprises:
forming a first photoresist layer over the metallic layer;
forming a second photoresist layer over the surface of the film on the far side of the metallic layer, wherein the second photoresist layer has a plurality of second openings;
removing a portion of the film to form a plurality of second openings using the second photoresist layer as an etching mask; and
removing the first photoresist layer and the second photoresist layer.

6. The method of claim 5, wherein the first photoresist layer and the second photoresist layer are dry films or liquid photoresist layers.

7. The method of claim 1, further comprising a step of depositing flex coat material into some of the openings to form a flex coat layer after the step of forming the openings but before the step of forming the metallic leads.

8. The method of claim 1, wherein the step of patterning the metallic layer comprises:
forming a third photoresist layer over the metallic layer, wherein the third photoresist layer has a plurality of third openings;
forming a back coat over the film on the far side of the metallic layer;
removing a portion of the metallic layer to form the metallic leads using the third photoresist layer as a mask; and
removing the third photoresist layer and the back coat.

9. The method of claim 8, wherein before forming the third photoresist layer, further comprises performing a surface treatment of the metallic layer.

10. The method of claim 9, wherein the surface treatment comprises performing a chemical polishing or a micro etching process.

11. The method of claim 1, wherein after forming the metallic leads, further comprises forming a first solder flux layer on the metallic leads.

12. The method of claim 11, wherein the first solder flux layer comprises a tin layer.

13. The method of claim 11, further comprising a step of forming an anti-soldering layer on the surface of a portion of the first solder flux layer after the step of forming the first solder flux layer.

14. The method of claim 13, further comprising a step of forming a second solder flux layer over the remaining surface of the first solder flux layer after the step of forming the anti-soldering layer.

15. The method of claim 14, wherein the second solder flux layer comprises a tin layer.

16. The method of claim 1, further comprising a step of performing an inspection of the finished product after the step of forming the metallic leads.
